(19) United States
(12) Patent Application Publication
(10) Pub. No.: US 2017/0187005 A1
(43) Pub. Date: Jun. 29, 2017

(54) OLED DISPLAY PANEL AND METHOD OF MANUFACTURING THE SAME

(71) Applicant: EVERDISPLAY OPTRONICS (SHANGHAI) LIMITED, SHANGHAI (CN)

(72) Inventors: Yanhu LI, SHANGHAI (CN); Xin MOU, SHANGHAI (CN)

(73) Assignee: EVERDISPLAY OPTRONICS (SHANGHAI) LIMITED, SHANGHAI (CN)

(21) Appl. No.: 15/189,126

(22) Filed: Jun. 22, 2016

(30) Foreign Application Priority Data
Dec. 25, 2015 (CN) 201510993328.2

(51) Int. Cl. H01L 51/52; H01L 51/56

(52) U.S. Cl. CPC H01L 51/5284; H01L 51/5237; H01L 51/56

(57) ABSTRACT

An OLED display panel with a method manufacturing the same includes: a substrate; an OLED display device, formed on the substrate; a cover plate, disposed on the substrate to seal the OLED display device; and a first resonant cavity layer, formed on the OLED display device and below the cover plate, configured to absorb blue light with wavelengths between 400 and 440 nm. By adjusting a resonant cavity length of the resonant cavity, the present disclosure changes a proportion of energy of blue light to a preset wavelength band in emitting light, significantly reduces a proportion of a spectrum below 435 nm to the preset wavelength band, and reduces material use of the resonant cavity layer, being conducive to improving device efficiency and reducing production cost, and being able to obtain eye-protecting effect at the same time.

### CROSS-REFERENCE TO RELATED APPLICATIONS

This application is based upon and claims priority to Chinese Patent Application No. 201510993328.2, filed on Dec. 25, 2015, the entire contents thereof are incorporated herein by reference.

### TECHNICAL FIELD

The present disclosure generally relates to the field of OLED display, and more particularly, to an OLED (organic light-emitting diode) display panel that may change a proportion of energy of blue light to a preset wavelength band in emitting light, and a method that may manufacture the OLED display panel.

### BACKGROUND

Along with increasing popularization of electronic products, controversies on whether long-time using of the electronic products may harm health or not, never comes to a stop. A focus point of the controversies and researches mainly concentrates on a radiation problem of display panels of the electronic products.

At present, increasingly improved LCD (liquid crystal display) and OLED technology has gradually replaced that of original CRT (cathode ray tube) displays. Compared with the CRT displays, radiation released by the LCD and OLED may be much smaller. However, a problem that radiation released by the LCD and OLED panel may harm eyes is still not solved perfectly.

Visible light is a kind of electromagnetic wave which is electromagnetic radiation. Thus, in broadly speaking, the visible light is also a kind of electromagnetic radiation. Generally, it is considered that the visible light does little harm to human body. The visible light refers to electromagnetic radiation visible to naked eyes, with wavelengths in a range from about 390 nm (Nanometer) to 760 nm in the electromagnetic spectrum. In a variety of visible lights, wavelengths of blue light are between 400 nm and 500 nm. Scientific research has verifies that: retinal cells contain an abnormal retinene, named A₂E in English. A₂E has two absorption peaks, one at 335 nm in an ultraviolet region, and the other at 435 nm in a blue light region. A₂E is toxic to the retinal pigment epithelium in the absence of light, i.e. in dark conditions, and its toxicity greatly increases under light conditions. At present, light sources of the most popular LCD and OLED contain abnormal high-energy short-wave blue light. At present, according to a kind of explanation, the so-called high-energy short-wave blue light is high strength and high brightness blue light whose wavelengths contain an absorption peak of A₂E, and are between 435 nm and 440 nm.

The high-energy short-wave blue light damages the retina by following steps: in the first step, since the A₂E has an absorption peak in the blue light region, the high-energy short-wave blue light can excite it to release radical ions; in the second step, these radical ions increase damage to retinal pigment epithelium, thus causing atrophy of the retinal pigment epithelium, and then causing death of light-sensitive cells. Function of the light-sensitive cells is to receive incident light and convert optical signals into electrical signals. The electrical signals are transmitted to the brain via optic nerve to form images. Death of the light-sensitive cells will cause vision gradually decreased or even completely lost.

At present, eye-protecting schemes against blue light are generally achieved by adjusting a resonant cavity of the OLED device. However, adding resonant cavity layer material will increase impedance of the OLED device. Therefore, power consumption of such device is large, which does not meet requirements of energy saving and environmental protection. In addition, cost of the resonant cavity layer material is high, which will raise cost of the OLED panel, and hinder rapid marketization of the OLED panel.

FIG. 1 is a sectional view of an OLED display panel of the prior art. As shown in FIG. 1, the OLED display panel of the prior art includes a substrate 1′, an OLED display device 2′, a light extracting layer 5′ and a cover plate 4′ stacked from bottom to top in sequence. A refractive index of the light extraction layer 5′ is greater than 1. The OLED display device 2′ includes an anode layer 21′, a hole injection layer 22′, a first resonant cavity layer 23′, a light emitting layer 24′, an electron transport layer 25′ and a cathode layer 26′ stacked from bottom to top in sequence. Since thicknesses of the first resonant cavity layer 23′ and the light emitting layer 24′ is large, according to the current scheme, the thickness of the first resonant cavity layer 23′ is 1050 Å. According to the resistance calculation formula:

R=ρL/S,

device resistance in the existing scheme is high, power consumption is large, requirement for the resonant layer material is high, cost is high, which is disadvantage to marketization of the OLED panel.

In view of this, the inventor provides an OLED display panel that may change a proportion of energy of blue light to a preset wavelength band in emitting light, and a method that may manufacture the OLED display panel.

### SUMMARY

Aiming at, at least a part, defects in the prior art, the present disclosure aims to provide an OLED display panel and a method of manufacturing an OLED display panel, which significantly reduces a proportion of a spectrum below 435 nm to a preset wavelength band in emitting light, reduces material use of the resonant cavity layer, and reduces a thickness of the resonant cavity layer to be 1000 Å or less, being conducive to improving device efficiency and reducing production cost, and being able to obtain eye-protecting effect at the same time.

According to an aspect of the present disclosure, there is provided an OLED display panel, including:

a substrate;

an OLED display device, formed on the substrate;

a cover plate, disposed on the substrate to seal the OLED display device; and

a first resonant cavity layer, formed on the OLED display device and below the cover plate, configured to absorb blue light with wavelengths between 400 nm and 440 nm emitted from the OLED display device.

For example, the first resonant cavity layer has a thickness between 0 and 1 μm.

For example, the first resonant cavity layer is of material of light-transmitting organic material with a refractive index greater than 1.

For example, the first resonant cavity layer is of material of NPB (4, 4′-double [N-(1-naphthyl)-N phenyl] biphenyl).

For example, the first resonant cavity layer has a resonant wavelength greater than 435 nm, and the first resonant cavity layer filters blue light with wavelengths less than or equal to 435 nm.

For example, the OLED display device includes:

an anode layer, formed on the substrate;

a hole injection layer, formed on the anode layer;

a second resonant cavity layer, formed on the hole injection layer, and the second resonant cavity layer and the first resonant cavity layer being both parallel plane cavities;

a light emitting layer, formed on the second resonant cavity layer;

an electron transport layer, formed on the light emitting layer; and

a cathode layer, formed on the electron transport layer.

For example, the second resonant cavity layer has a thickness below 500 nm.

For example, the second resonant cavity layer is of material of light-transmitting hole transport material.

For example, the second resonant cavity layer is of material of DNTPD (4′-double (N-{4-[N-(3-methyl phenyl)-N-phenyl amino] phenyl}-N-phenyl amino) biphenyl).

According to another aspect of the present disclosure, there is also provided a method of manufacturing an OLED display panel, including following steps:

providing a substrate;

forming an OLED display device on the substrate;

forming a first resonant cavity layer on the OLED display device, to absorb blue light with wavelengths between 400 nm and 440 nm emitted from the OLED display device;

and

providing a cover plate, on the OLED display device, to seal the OLED display device.

For example, the first resonant cavity layer is set to have a thickness between 0 and 1 μm.

For example, light-transmitting organic material with a refractive index greater than 1 is selected to form the first resonant cavity layer.

For example, material of NPB is selected to form the first resonant cavity layer.

For example, steps of manufacturing the OLED display device includes:

forming an anode layer on the substrate;

forming a hole injection layer on the anode layer;

forming a second resonant cavity layer on the hole injection layer, and setting the second resonant cavity layer and the first resonant cavity layer to be parallel plane cavities;

forming a light emitting layer on the second resonant cavity layer;

forming an electron transport layer on the light emitting layer; and

forming a cathode layer on the electron transport layer.

For example, a thickness of the second resonant cavity layer is formed with a thickness between 0 and 500 nm.

For example, light-transmitting hole transport material is selected to form the second resonant cavity layer.

For example, material of DNTPD is selected to form the second resonant cavity layer.

An OLED display panel and a method that may manufacture the OLED display panel according to the present disclosure reduces the thickness of the second resonant cavity between the cathode layer and the anode layer, adjusts a resonant cavity length of the first resonant cavity on the cathode layer, and changes the proportion of energy of blue light to the preset wavelength band in emitting light. Therefore, the proportion of the spectrum below 435 nm to the preset wavelength band may be significantly reduced, and material use of the second resonant cavity layer may be reduced, which may be conducive to improving device efficiency and reducing production cost, and may be able to obtain eye-protecting effect at the same time.

### BRIEF DESCRIPTION OF THE DRAWINGS

Other features, objects and advantages of the present disclosure will become more apparent by describing its non-restrictive embodiments in detail with reference to following drawings.

FIG. 1 is a sectional view of an OLED display panel of the prior art;

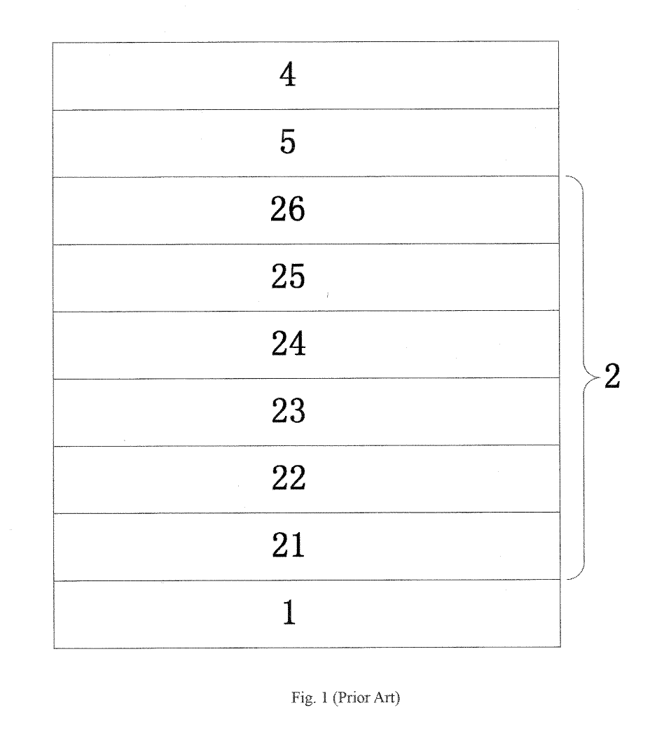

FIG. 2 is a sectional view of an OLED display panel according to the present disclosure;

FIG. 2A is a flow chat of a method of manufacturing the OLED display panel shown in FIG. 2 according to the present disclosure;

FIG. 2B is a flow chat of steps of manufacturing the OLED display device 2 shown in FIG. 2 according to the present disclosure; and

FIG. 3 is spectrum comparison diagram with respect to devices having first resonant cavity layers with different resonant cavity thicknesses.

### LISTING OF REFERENCE SIGNS

1′ substrate
2′ OLED display device
21′ anode layer
22′ hole injection layer
23′ first resonant cavity layer
24′ light emitting layer
25′ electron transport layer
26′ cathode layer
4′ cover plate
5′ light extracting layer
1 substrate
2 OLED display device
21 anode layer
22 hole injection layer
23 second resonant cavity layer
24 light emitting layer
25 electron transport layer
26 cathode layer
3 first resonant cavity layer
4 cover plate

### DETAILED DESCRIPTION

Now, exemplary implementations will be described more comprehensively with reference to the accompanying drawings. However, the exemplary implementations may be carried out in various manners, and shall not be interpreted as being limited to the implementations set forth herein; instead, providing these implementations will make the present disclosure more comprehensive and complete and will fully convey the conception of the exemplary implementations to the ordinary skills in this art. Throughout the drawings, the like reference signs refer to the same or the like structures, and repeated descriptions will be omitted.

The features, structures or characteristics described herein may be combined in one or more implementations in any suitable manner. In the following descriptions, many specific details are provided to facilitate sufficient understanding of the implementations of the present disclosure. However, one of ordinary skills in this art will appreciate that the technical solutions in the present disclosure may be practiced without one or more of the specific details, or by employing other methods, components, materials and so on. In other conditions, well-known structures, materials or operations are not shown or described in detail so as to avoid confusion of respective aspects of the present disclosure.

Drawings of the present disclosure are provided for illustrating relative position relations, layer thicknesses of some parts are exaggerated for ease of understanding, and diameters of lines and intervals in the drawings do not indicate actual size and scale. The terms of “on”, “below” or the like used herein are non-restrictive wordings to facilitate describing relative directions with reference of a drawing sheet.

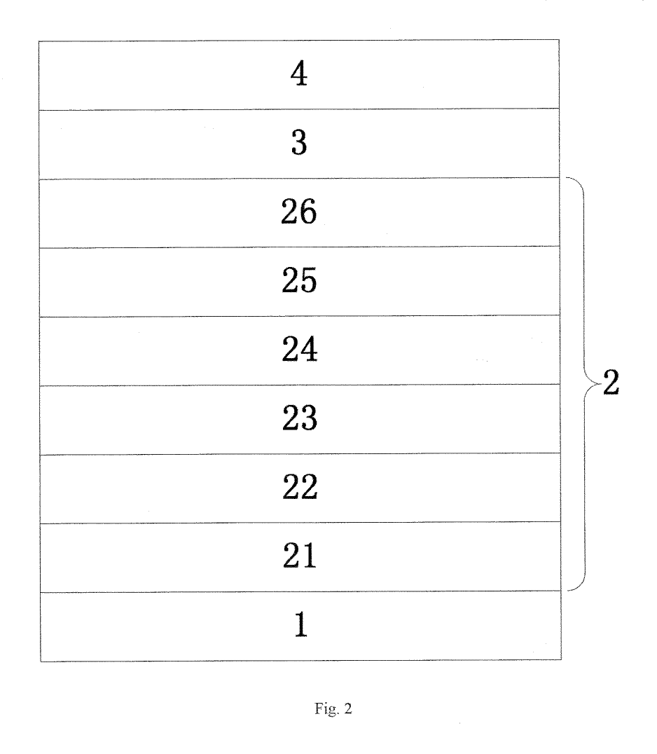

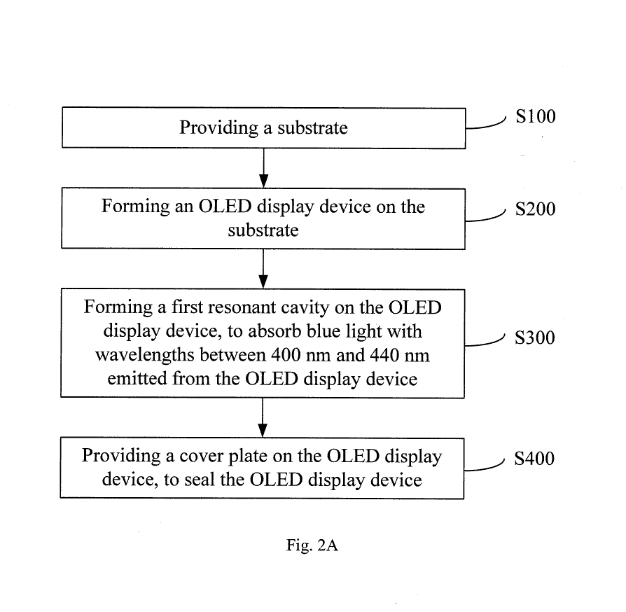

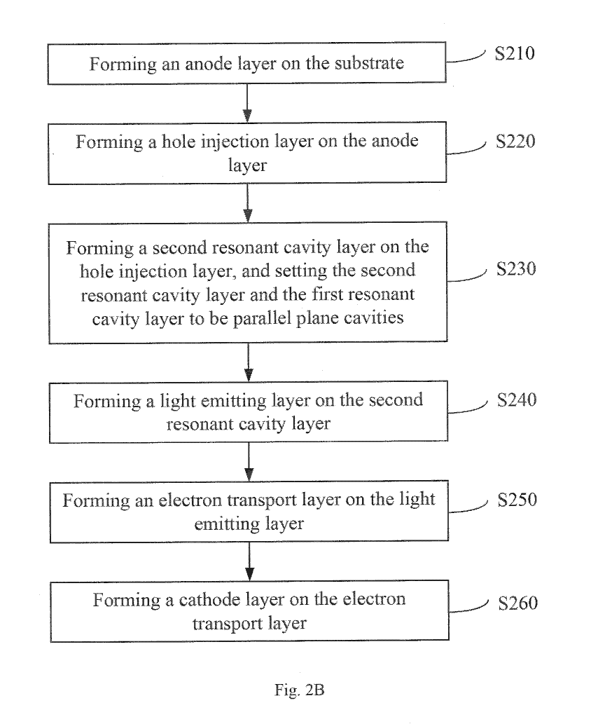

FIG. 2 is a sectional view of an OLED display panel according to the present disclosure. As shown in FIG. 2, the embodiment of the present disclosure provides an OLED display panel, including: a substrate 1, an OLED display device 2, a first resonant cavity layer 3 and a cover plate 4. The OLED display device 2 is formed on the substrate 1. The cover plate 4 is covered on the OLED display device 2 and glued with the substrate 1 for sealing. The first resonant cavity layer 3 is formed on the OLED display device 2 and below the cover plate 4, configured to absorb blue light with wavelengths between 400 nm and 440 nm emitted from the OLED display device.

The OLED display device 2 of the present disclosure includes: an anode layer 21, a hole injection layer 22, a second resonant cavity layer 23, a light emitting layer 24, an electron transport layer 25 and a cathode layer 26, but not limited to this. According to an embodiment, the anode layer 21 is formed on the substrate 1, the hole injection layer 22 is formed on the anode layer 21, the second resonant cavity layer 23 is formed on the hole injection layer 22, the second resonant cavity layer 23 and the first resonant cavity layer 3 are both parallel plane cavities, the light emitting layer 24 is formed on the second resonant cavity layer 23, the electron transport layer 25 is formed on the light emitting layer 24, and the cathode layer 26 is formed on the electron transport layer 25. According to an embodiment, the second resonant cavity layer 23 has a thickness below 500 nm, and the second resonant cavity layer 23 is of material of light-transmitting hole transport material. The second resonant cavity layer 23 may be of material of DNTPD (4′-double (N-{4-[N-(3-methyl phenyl)-N-phenyl amino] phenyl}-N-phenyl amino) biphenyl), and the light emitting layer 24 may be of material of TPBI (1, 3, 5-(three N-phenyl-2-benzo imidazole-2) benzene 41), but not limited to this.

The first resonant cavity layer 3 according to the present disclosure may replace the light extracting layer of the OLED display panel in the prior art, having both light extracting function and resonant cavity function at the same time. For example, the first resonant cavity layer 3 has a thickness between 0 and 1 μm, but not limited to this. It may have larger thickness. By increasing the thickness of the first resonant cavity layer 3, a red shift of a blue light spectrum may be obtained, so as to achieve an aim of removing blue light harmful to eyes. The first resonant cavity layer 3 has a resonant wavelength greater than 435 nm. The first resonant cavity layer 3 filters blue light with wavelengths less than or equal to 435 nm. In addition, the first resonant cavity layer 3 is of material of light-transmitting organic material with a refractive index greater than 1. The first resonant cavity layer 3 may be of material of NPB (4, 4′-double [N-(1-naphthyl)-N phenyl] biphenyl), but not limited to this. An average N value (refractive index) of the NPB material is greater than 1.5, and cost of the material is low, so that the NPB material is preferable material serving as the first resonant cavity layer 3. The first resonant cavity layer 3 may also be of material of CBP (4, 4′-double (N-carbazole)-1, 1′-biphenyl).

Since the first resonant cavity layer 3 does not participate in electrical function of the OLED device, material choice range is wide and cost is low. Meanwhile, the light extracting layer is not needed any more after the first resonant cavity layer 3 is added. The first resonant cavity layer 3 may replace function of the light extracting layer. In addition, compared with the light extracting layer, the first resonant cavity layer 3 needs no special process, and the material thereof may also be obtained by mixing several kinds of material.

A principle that the first resonant cavity layer 3 filters high-energy short-wave blue light lies in that the first resonant cavity layer 3 is also a resonant cavity layer, which enhances light having wavelength (for example, 400 nm) according with its resonant cavity length, while suppresses light having wavelength (for example, less than 400 nm) not according with its resonant cavity length. Thus, the blue light less than or equal to 435 nm may be removed, so that an effect of removing harmful deep blue light may be achieved.

On the basis of cooperation of the first resonant cavity layer and the second resonant cavity layer, technical solutions in which texture composition, thicknesses and structures of the second resonant cavity layer and the first resonant cavity layer are varied, and technical solutions in which other light-transmitting layers are added between the second resonant cavity layer and the first resonant cavity layer, all fall into the protection scope of the present disclosure.

FIG. 2A is a flow chat of a method of manufacturing the OLED display panel shown in FIG. 2 according to the present disclosure, As shown in FIG. 2A, according to another aspect of the present disclosure, there is also provided a method of manufacturing the OLED display panel, including following steps:

firstly, step S100, providing a substrate;

next, step S200, forming an OLED display device on the substrate;

next, step S300, forming a first resonant cavity on the OLED display device, to absorb blue light with wavelengths between 400 nm and 440 nm emitted from the OLED display device; and

finally, step S400, providing a cover plate, on the OLED display device, to seal the OLED display device.

According to an embodiment, the first resonant cavity layer is set to have a thickness between 0 and 1 μm, but not limited to this. Light-transmitting organic material with a refractive index greater than 1 is selected to form the first resonant cavity layer. Material of NPB is selected to form the first resonant cavity layer.

FIG. 2B is a flow chat of steps of manufacturing the OLED display device 2 shown in FIG. 2 according to the present disclosure. As shown in FIG. 2B, according to an embodiment, steps of manufacturing the OLED display device includes:

step S210, forming an anode layer on the substrate;

step S220, forming a hole injection layer on the anode layer;

step S230, forming a second resonant cavity layer on the hole injection layer, and setting the second resonant cavity layer and the first resonant cavity layer to be parallel plane cavities;

step S240, forming a light emitting layer on the second resonant cavity layer;

step S250, forming an electron transport layer on the light emitting layer; and

step S260, forming a cathode layer on the electron transport layer.

According to an embodiment, the second resonant cavity layer is formed with a thickness between 0 and 500 nm. Light-transmitting hole transport material is selected to form the second resonant cavity layer. Material of DNTPD is selected to form the second resonant cavity layer. Other technical features are the same as that of the above OLED display panel shown in FIG. 2, which will not be repeatedly illustrated herein.

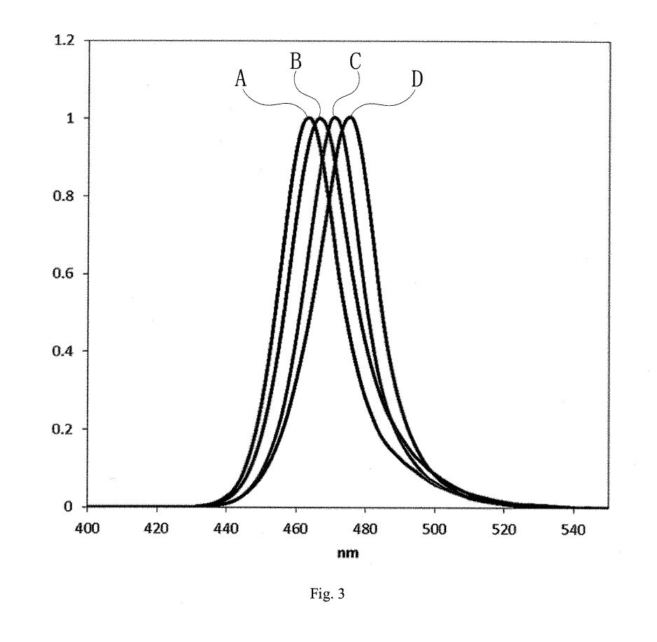

FIG. 3 is spectrum comparison diagram with respect to devices having first resonant cavity layers with different resonant cavity thicknesses. As shown in FIG. 3, the horizontal axis is blue light wavelength in a preset wavelength band in the emitting light, the vertical axis is a proportion of spectral components to the preset wavelength band, which can substantially reflect a proportion of blue light with wavelengths below 435 nm to the preset wavelength band, and curves from left to right respectively represent:

curve A represents an OLED panel of a standard device of the prior art;

curve B represents an OLED panel having the first resonant cavity layer with a thickness of 600 Å according to the present disclosure;

curve C represents an OLED panel having the first resonant cavity layer with a thickness of 800 Å according to the present disclosure; and

curve D represents an OLED panel having the first resonant cavity layer with a thickness of 1000 Å according to the present disclosure.

The proportions of the blue light with wavelengths below 435 nm to the preset wavelength band in the above four curves are listed in the following table:

| structure of device | standard device | 600 Å | 800 Å | 1000 Å |
|---|---|---|---|---|
| proportions of the blue light | 0.07% | 0.03% | 0.017% | 0.01% |
| with wavelengths below | | | | |
| 435 nm | | | | |

Compared with curve A, material of the first resonant cavity layers in curve B, curve C and curve D is the same as that of the light extracting layer in curve A, expect that the thicknesses are changed. Compared with curve A, thicknesses of the second resonant cavity layers in curve B, curve C and curve D may be around 1040 Å, but not be fixed to this.

It can be seen that, compared with the standard device (i.e. the prior art), along with increasing of the thickness of the first resonant cavity layer, the spectrum below 435 nm in the present disclosure reduces gradually, such that the present disclosure achieves an aim that the spectrum below 435 nm may not be emitted. It is known that a proportion of spectral component below 435 nm to the preset wavelength band in the standard device is 0.07%. As the thickness of the first resonant cavity layer increases from 600 Å to 1000 Å, a proportion of spectral component below 435 nm to the preset wavelength band is reduced from 0.03% to 0.01%, such that a better eye-protecting effect is achieved. Meanwhile, since the spectrum gradually red shifts along with the increasing of the thickness of the first resonant cavity layer, an aim of adjusting the spectrum may be achieved by changing the thickness of the first resonant cavity layer. Therefore, material use of the second resonant cavity layer may be reduced, which may be conducive to improving device efficiency and reducing production cost, and may be able to obtain eye-protecting effect at the same time, which will not be repeatedly illustrated herein. Compared with the prior art, the thickness of the second resonant cavity layer in the structure of the present disclosure may be reduced to 0 to 200 Å.

To sum up, an OLED display panel and a method that may manufacture the OLED display panel according to the present disclosure reduces the thickness of the second resonant cavity between the cathode layer and the anode layer, adjusts the resonant cavity length of the first resonant cavity on the cathode layer, and changes the proportion of energy of blue light to the preset wavelength band in emitting light. Therefore, the proportion of the spectrum below 435 nm to the preset wavelength band may be significantly reduced, and material use of the second resonant cavity layer may be reduced, which may be conducive to improving device efficiency and reducing production cost, and may be able to obtain eye-protecting effect at the same time.

Detailed embodiments of the present disclosure are illustrated above. It should note that, the present disclosure is not limited to the above specific implementations. Those skilled in the art may make various transformations or amendments within the protection scope of claims, which does not influence essential content of the present disclosure.

What is claimed is:

1. An OLED display panel, comprising:
a substrate;
an OLED display device, formed on the substrate;
a cover plate, disposed on the substrate to seal the OLED display device; and
a first resonant cavity layer, formed on the OLED display device and below the cover plate, configured to absorb blue light with wavelengths between 400 nm and 440 nm emitted from the OLED display device.

2. The OLED display panel according to claim 1, wherein the first resonant cavity layer has a thickness between 0 and 1 μm.

3. The OLED display panel according to claim 1, wherein the first resonant cavity layer is of material of light-transmitting organic material with a refractive index greater than 1.

4. The OLED display panel according to claim 3, wherein the first resonant cavity layer is of material of NPB.

5. The OLED display panel according to claim 1, wherein the OLED display device comprises:
an anode layer, formed on the substrate;
a hole injection layer, formed on the anode layer;
a second resonant cavity layer, formed on the hole injection layer, and the second resonant cavity layer and the first resonant cavity layer being both parallel plane cavities;
a light emitting layer, formed on the second resonant cavity layer;
an electron transport layer, formed on the light emitting layer; and
a cathode layer, formed on the electron transport layer.

6. The OLED display panel according to claim 5, wherein the second resonant cavity layer has a thickness below 500 nm.

7. The OLED display panel according to claim 6, wherein the second resonant cavity layer is of material of light-transmitting hole transport material.

8. The OLED display panel according to claim 7, wherein the second resonant cavity layer is of material of DNTPD.

9. A method of manufacturing an OLED display panel, comprising:
providing a substrate;
forming an OLED display device on the substrate;
forming a first resonant cavity layer on the OLED display device, to absorb blue light with wavelengths between 400 nm and 440 nm emitted from the OLED display device; and
providing a cover plate on the OLED display device to seal the OLED display device.

10. The method according to claim 9, wherein the first resonant cavity layer is set to have a thickness between 0 and 1 μm.

11. The method according to claim 9, wherein light-transmitting organic material with a refractive index greater than 1 is selected to form the first resonant cavity layer.

12. The method according to claim 11, wherein material of NPB is selected to form the first resonant cavity layer.

13. The method according to claim 9, wherein steps of manufacturing the OLED display device comprises:
forming an anode layer on the substrate;
forming a hole injection layer on the anode layer;
forming a second resonant cavity layer on the hole injection layer, and setting the second resonant cavity layer and the first resonant cavity layer to be parallel plane cavities;
forming a light emitting layer on the second resonant cavity layer;
forming an electron transport layer on the light emitting layer; and
forming a cathode layer on the electron transport layer.

14. The method according to claim 13, wherein the second resonant cavity layer is formed with a thickness between 0 and 500 nm.

15. The method according to claim 14, wherein light-transmitting hole transport material is selected to form the second resonant cavity layer.

16. The method according to claim 15, wherein material of DNTPD is selected to form the second resonant cavity layer.
